(19) United States
(12) Patent Application Publication
(10) Pub. No.: US 2006/0057861 A1
(43) Pub. Date: Mar. 16, 2006

(54) Movable operating device and method of controlling the movable operating device

(75) Inventors: Masaharu Goto, Hanno-shi (JP); Shinichiro Iwasaki, Hino-shi (JP)

Correspondence Address: Paul D. Greeley, Esq.;Ohlandt, Greeley, Ruggiero & Perle, L.L.P., One Landmark Square, 10th Floor, Stamford, CT, 06901-2682, US

(73) Assignee: Agilent Technologies, Inc.

(21) Appl. No.: 11/217,525

(22) Filed: Sep. 1, 2005

(30) Foreign Application Priority Data
Sep. 14, 2004 (JP) 2004-266624

(51) Int. Cl. H01L 21/00

(52) U.S. Cl. 438/800

(57) ABSTRACT

The movable operating device includes a frame for fixedly supporting an object having a first surface, a plurality of movable members movably supported on the frame, and a movement control device for moving the movable members for positioning. At least one of the plurality of movable members includes an operating portion that is opposed to the first surface to perform an operation on the first surface. At least two of the plurality of movable members are driven by the movement control device such that respective reaction forces that are generated upon driving those movable members are reduced by each other, thereby restraining those reaction forces from being exerted on the frame.

### BACKGROUND OF THE INVENTION

This invention relates generally to a positioning technique for an object, and more particularly to a movable operating device enabling both high-speed and high-precision positioning requiring a smaller footprint and to a method of controlling the movable operating device.

In recent years, devices and methods for performing various operations on a plate-like object are frequently used, and efforts have been made to achieve improvements in the speed, precision, accuracy, and stability of the positioning between an operating portion for performing an operation and the plate-like object, greater ease of use, and reductions in the footprint and cost. Examples of those devices include testing and inspection devices such as a device for testing and inspecting mounted/unmounted circuit board, a semiconductor wafer testing and inspection device, and an atomic force microscope, and shaping/processing devices such as a solid (three-dimensional) freeform fabrication (assembly) device, dispensers of various kinds, and an exposure system for forming patterns on a substrate (particularly one that performs collective exposure).

Examples of the plate-like object include a mounted/unmounted circuit board, a semiconductor wafer, and a physical object in general. Although such a plate-like object is generally plate-shaped, it may not necessarily have a plate-like shape as far as its surface is flat. The operating portion is the distal end portion of a probe, probe needle, pen, nozzle, or the like, which is brought very close to or into contact with the plate-like object. Over the years, there has been a demand for operating portions with smaller diameters. Depending on the case, such a distal end portion may be held in contact with (adjoining) or in non-contact with (close to) the plate-like object that is under a target operation.

In those devices, one or both of the operating portion and plate-like object are “moved” with respect to a stationary frame (stage) of the device, whereby a relative positioning is effected to perform various operations. Examples of those “operations” include emitting/receiving of light or electromagnetic energy for making measurements, emitting/receiving of charged particles, transmitting of a substance (liquid or solid), and detection of an attracting force. In view of this, in this specification, those devices are generically referred to as a “movable operating device”. Generally, components requiring small energy for their movement and having small sensitivity to high-speed movement are chosen as the components to be moved.

FIG. 1A is a partial sectional side view of a conventional testing device 100 for performing a test on a glass substrate 101 on which surface thin film transistors (TFTs) are formed. FIG. 1B is a partial sectional side view of the testing device 100 as seen from the direction perpendicular to FIG. 1A. In general, a known XY stage, equipped with an X direction drive mechanism 106 and a Y direction drive mechanism 105, is fixed onto a base 107 that is fixed to the high-rigidity frame 110 disposed on a pedestal frame through a vibration isolating structure. A stage 103 is mounted on the XY stage through a Z direction drive mechanism 104. A substrate 101 is chucked and retained on the stage 103. On the other hand, a probe unit 102 connected to a test head 108 supported on another member or the frame 110 is equipped with a number of probes; when the Z direction drive mechanism 104 is actuated to elevate the substrate 101, the probes come to a position close to or adjoining the top surface of the substrate 101, thereby effecting a measurement, in other words, an operation or the like necessary for the testing of the substrate 101. On the other hand, when the Z direction drive mechanism 104 is activated to lower the substrate 101, the probes are separated from the top surface thereof, and then the XY stage is activated, whereby the stage 103 is moved in the X direction (horizontal direction along the plane of FIG. 1A) and in the Y direction (direction perpendicular to the plane of FIG. 1A) for positioning, making ready for the next operation for testing.

Conventionally, various improvements have been made to those devices. JP 08-075828 A discloses an inspection device that measures an LCD (liquid crystal display) panel on an X-Y stage with small electro-optical (E-O) proves. A plurality of (8 to 40) E-O probes are used to achieve an arrangement equivalent to one using an elongated electro-optical probe, thereby enhancing the speed of measurement at a predetermined position on the panel. In the wafer inspection device disclosed in JP 10-275835 A, in order to avoid an increase in the size of the probe unit due to an increase in the wafer size, an arrangement is employed in which one wafer stage and a plurality of testers are provided, thereby reducing the inspection time without increasing the footprint of the inspection device. On the other hand, the circuit board inspection device disclosed in JP 2002-31661 A is equipped with a plurality of large movable probe heads and performs inspection on a stationary circuit board. Each large probe head is mounted with a plurality of small probe heads. One small probe head is driven in the vicinity of the large probe head with a driving cam, whereby the distance to the other small probes can be adjusted in a continuously variable manner. The number of the probe heads thus decreases. Further, JP 2002-221249 A discloses a technique according to which an actuator is mounted on a frame, and the vibration of the frame caused by a movable member is actively controlled by the reaction force that is generated by driving the actuator, thereby achieving enhanced precision of the exposure device.

With the device shown in FIG. 1, although the glass substrate 101 to be moved has relatively lower sensitivity to the movement, the device must be designed on an assumption that as the glass substrate is enlarged in size, the mass of the movable member including a drive system might exceed 100 kg. It is difficult to quickly move a thing with such a large mass. Further, the base 107 requires an even larger mass, so the overall weight of the device becomes extremely heavy. Since a large substrate moves by as much as 1 m or more beyond the substrate dimensions, the footprint of the device increases.

Although the technique described in JP 08-075828 A may be adopted for the device shown in FIG. 1 to provide a large number of probes, there is a limit as to how many probes can be provided, and it is difficult to effect positioning on such a large number of probes and keep them in an operation state. Further, there still is the requirement of moving a large mass. Substantially the same problems remain even when the technique described in JP 10-275835 is adopted. It may be expected that if the technique described in JP 2002-31661 A is employed, the installation area is reduced since the substrate remains stationary, thereby avoiding the problem of the movement of a member having a large mass. However, the respective probe heads move one by one or move without having a particular coordinated relationship with other probe heads, so the reaction forces accompanying the movement thereof are transmitted through the probe head drive mechanism to cause other components to vibrate, making it difficult to perform high-speed, precision positioning. When, in view of the above problems, the technique described in JP 2002-221249 is employed and actuators are provided to the support member of the drive mechanism to effect vibration control by means of the drive reaction forces of the actuators, such an arrangement is not practical because it is necessary to provide a large number of actuators and perform extremely complex control. Further, basically, the number of actuators should be minimized since they do not directly contribute to the inspection itself.

Therefore, in a device for performing an operation on a stationary member wherein the device is provided with a plurality of movable members such as test heads movably supported on a frame or the like, there is a demand for an efficient movable operating device and a method of controlling the movable operating device being capable of reducing the influence of drive reaction forces on the frame, which influence is caused by the movement of the movable members.

### SUMMARY OF THE INVENTION

A movable operating device according to this invention includes: a frame for fixedly supporting an object having a first surface; a plurality of movable members movably supported by the frame; and a movement control device for moving the movable members for positioning. Of the plurality of movable members, at least one movable member includes an operating portion that is opposed to the first surface to perform an operation on the first surface, and the at least two movable members are driven by the movement control device such that respective reaction forces that are generated upon driving the at least two movable members and exerted on the frame are reduced by each other.

A method of controlling a movable operating device according to this invention is applied to a movable operating device including: a frame; a plurality of movable members movably supported by the frame; and a movement control device for moving the plurality of movable members for positioning. The method includes the steps of: fixedly supporting an object having a first surface on the frame; moving at least two of the plurality of movable members in an opposed mannerwith respect to the first surface; and positioning and stopping at least two of the plurality of movable members in place, and is characterized in that at least two of the plurality of movable members are driven by the movement control device such that respective reaction forces that are generated upon driving the at least two movable members and exerted on the frame are reduced by each other.

Other features and effects of this invention will become apparent from the following description.

### BRIEF DESCRIPTION OF THE DRAWINGS

FIG. 1A is a partial sectional side view (front view of a frame) of a conventional testing device for performing a test on a glass substrate having a thin film transistor (TFT) formed thereon.

FIG. 1B is a partial sectional side view of the conventional testing device as seen in the direction perpendicular to the direction of FIG. 1A.

FIG. 2 is a partial sectional side view for illustrating the principle of this invention, showing conceptual construction of a movable operating device.

FIG. 3A is a partial sectional side view of a substrate inspection device according to an embodiment of this invention as seen in the Y direction.

FIG. 3B is a partial sectional side view of the substrate inspection device according to the embodiment of this invention as seen in the X direction perpendicular to the Y direction.

FIG. 3C is a sectional view of the substrate inspection device according to the embodiment of this invention taken along the line C-C of FIG. 3A (It should be noted that a frame is omitted).

FIG. 4 is a trajectory chart exemplifying a trajectory which each of probe units follows on a glass substrate.

FIG. 5A is a partial sectional plan view, taken along the line A-A of FIG. 5C, of a drive mechanism including Z direction drive mechanism which is a part of a moving member associated with an X direction drive mechanism.

FIG. 5B is a partial sectional plan view of the drive mechanism taken along the line B-B of FIG. 5C.

FIG. 5C is a sectional view of the drive mechanism taken along the line C-C of FIGS. 5A and 5B.

FIG. 6 is a graph showing changes in time series in respective operating parameters of the drive mechanism.

FIG. 7A is a sectional view of a drive mechanism according to another embodiment of this invention taken along the line A-A of FIG. 7B.

FIG. 7B is a sectional view of the drive mechanism according to another embodiment of this invention taken along the line B-B of FIG. 7A.

### DETAILED DESCRIPTION

Embodiments of this invention described below are provided to facilitate the understanding of this invention and are not intended to limit this invention to those specific embodiments. Therefore, the dimensions and configurations of devices and their components are not intended to have a particular geometric relation to the dimensions and configurations of devices and components which are actually manufactured. Further, the same reference numerals are attached to devices and their components whose functions are considered similar, although not completely identical to each other for the purpose of better understanding of this invention. Further, in the following description of the embodiments, the description is given of only those wirings for the connection of components or components performing electrical or mechanical actions which are necessary for the understanding of this invention. Further, the description relating to the prior art is omitted or simplified.

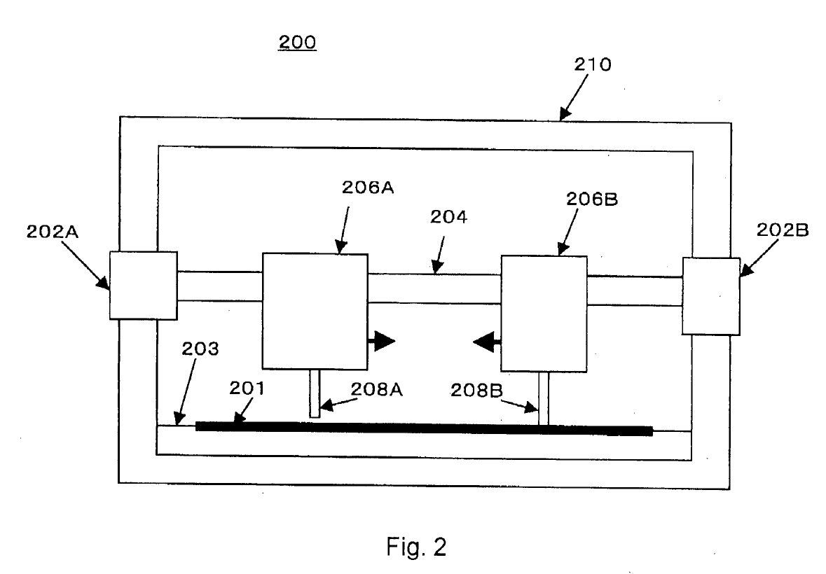

FIG. 2 is a partial sectional side view showing the conceptual construction of a movable operating device 200 and illustrating the principle of this invention. An object 201 such as a glass substrate having a first surface is inserted from outside to be fixedly supported on a base 203 that is fixedly disposed on a frame 210 having a high rigidity. Examples of the glass substrate used may include a display panel or a TFT panel for one or more display panels as an object to be measured. Mounted on the frame 210 are drive devices 202A and 202B such as motors that drive a drive shaft 204. Movable members 206A and 206B such as test heads are mounted on the drive shaft 204 so as to move in the lateral direction. The movable members 206A and 206B are equipped with operating portions 208A and 208B, respectively. One of the drive devices 202A and 202B may not have a driving function, like a bearing. Each movable member is positioned to a target position of an object by a movement control device composed of the drive devices and the drive shaft. Then, with a known method, the operating portion of the movable member is extended (retracted during the movement) to a position close to (in a non-contacting manner as indicated by the operating portion 208A) or adjoining (in a contacting manner as indicated by the operating portion 208B) the object, whereby an operation (such as the measurement of the object) is performed. Here, the movable member may have a function of measuring an object through an electrical, optical, electromagnetic, or other such method.

When performing the above positioning, the movable members 206A and 206B move in opposite directions, so the reaction forces acting on the drive shaft are canceled out and decreased.

Therefore, the resultant of forces acting in one direction of the frame is considerably reduced through the cancellation of the forces as compared with a reaction force that is generated when each of the movable members 206A and 206B is driven independently. Since the reaction forces act in opposite directions, when the respective reaction forces are equal, the resultant force becomes zero. In this way, according to this invention, vibration control is automatically effected without additionally providing a vibration control device such as an actuator, thereby realizing efficient and simplified construction.

It should be noted that, according to the principle of this invention, the orientation of the movable operating device 200 may be different from that shown in the drawing (for example, it may be arranged upside down). As will be described later, the drive shaft 204 used may be a ball screw device with guide rails attached, wherein the drive shaft 204 is driven by a servomotor. As the movement control device, there may be used a drive device utilizing a timing belt, a linear motor, or the like. Further, the number of the movable members is not limited to two. Further, by means of a movement control device including a drive shaft extending in another direction, another movable member may be provided such that the resultant of the reaction forces of the individual movable members is reduced. Further, it is also possible to mount an additional movement control device to the above-mentioned movable members, the additional movement control device comprising a plurality of movable members and being constructed so as to reduce the resultant of their individual reaction forces of the moveable members in the additional movement control device. Further, while the above description is directed to the movable members each making a linear motion, it will be appreciated that this invention is also applicable to movable members that make rotary motions in opposite directions.

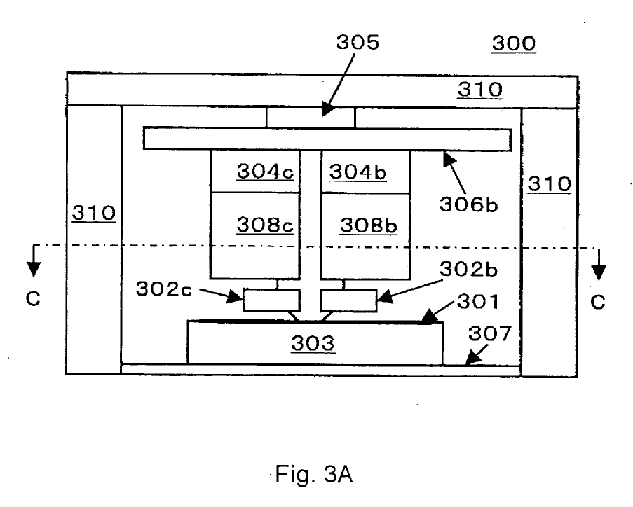

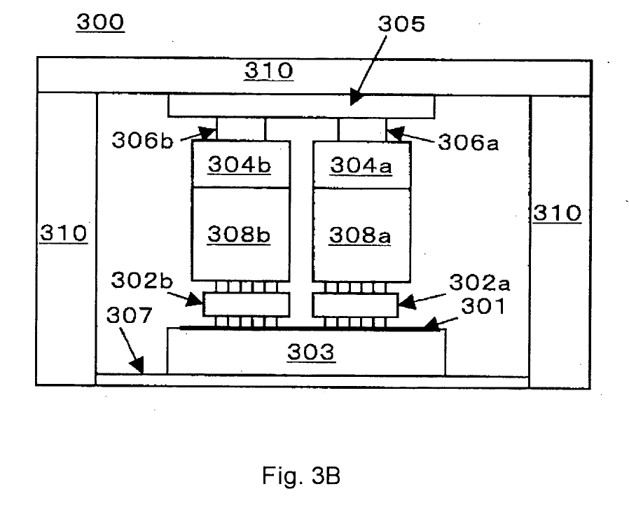

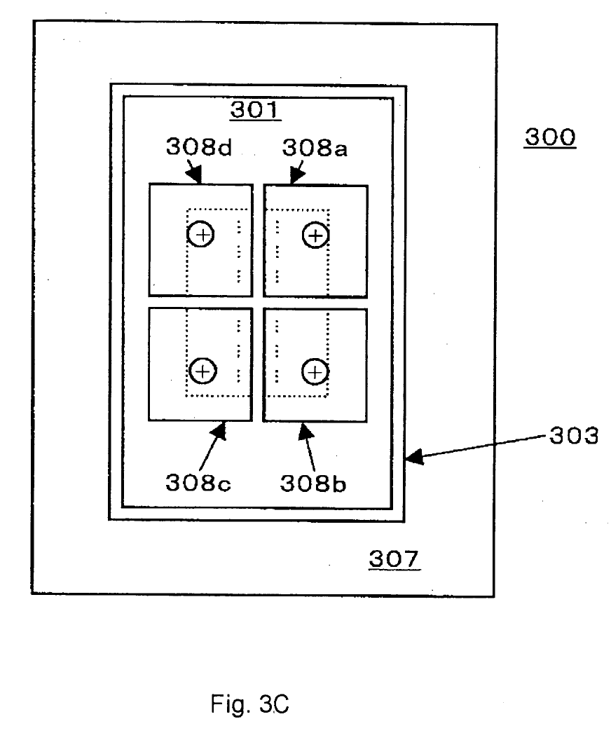

FIGS. 3A through 3C show a substrate inspection device 300 that is a movable operating device according to an embodiment of this invention. FIG. 3A is a partial sectional side view of the substrate inspection device 300 that is the movable operating device according to the embodiment of this invention as seen in the Y direction. FIG. 3B is a partial sectional side view of the substrate inspection device 300 according to the embodiment of this invention as seen in the X direction perpendicular to the Y direction. FIG. 3C is a sectional plan view of the portion C-C of the substrate inspection device 300 according to the embodiment of this invention shown in FIG. 3A (however, a frame 310 is not shown in FIG. 3C). The substrate inspection device 300 is equipped with four movable members, in other words, four sets of an assembly including a probe unit, a test head, and a Z drive shaft, which are arranged to perform an operation on a substrate in parallel. With all of the four sets having substantially the same construction, the throughput obtained can be increased by approximately four times. Further, by additionally providing operating portions with which the individual sets can be operated in parallel, the throughput of the operation increases by multiples of four.

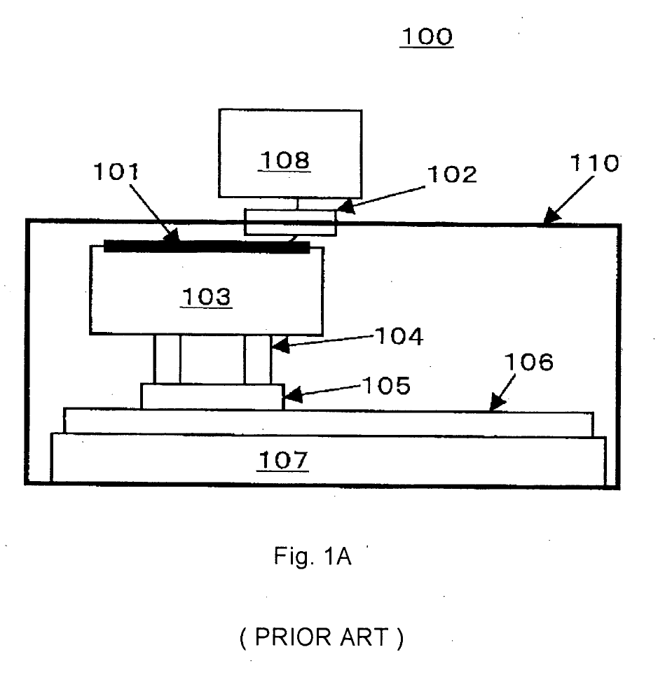

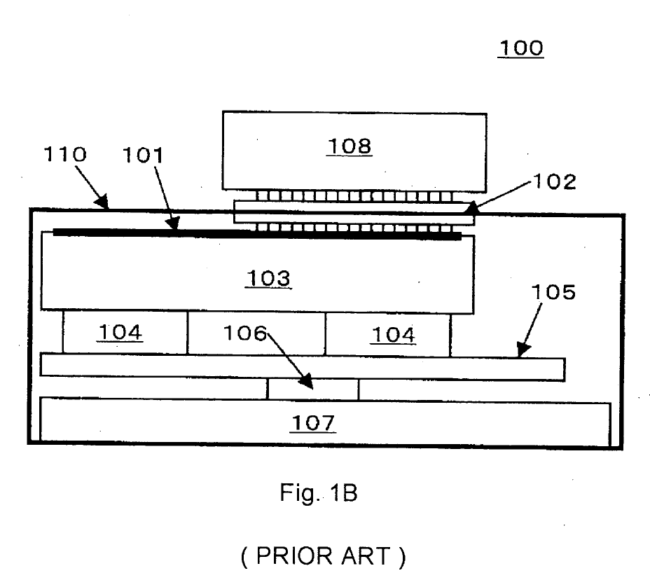

The substrate inspection device 300 is equipped with a frame 310 having a high rigidity equivalent to those of the frame 110 shown in FIGS. 1A and 1B and of the frame 210 shown in FIG. 2. The frame 310 includes a top wall, a bottom wall, and sidewalls that are joined together with a desired rigidity. As is conventionally known, the frame 310 is formed of a conductive high-rigidity material such as metal, preferably steel, and may be arranged as the frame or casing of a device. The bottom wall, onto which a base 307 is joined and placed with a required rigidity, is not shown in FIGS. 3A and 3B. As in the prior art, the bottom wall is joined to a pedestal frame or the like through the intermediation of a vibration isolating mechanism. As in the prior art, each sidewall or the like is generally provided with an opening or door for carrying in and out the glass substrate 301. A Y drive shaft 305, which is fixed to the top wall of the frame 310, suspends X drive shafts 306a and 306b so as to allow their movement, thereby enabling the movement of probes at least over a distance equal to the length of one side of the rectangular glass substrate 301. The X drive shafts 306a and 306b, which serve to move the probes in the direction perpendicular to the direction in which the probes are driven along the Y drive shaft, enable the movement of the probes at least over the distance equal to the length of the other side of the rectangular glass substrate 301.

A stage 303 is fixed and placed onto the base 307 fixed to the high-rigidity frame 310, and chucking is effected for retention after the carrying-in of the glass substrate 301. As shown in the drawing, arranged above the glass substrate 301 are probe units 302a, 302b, 302c, and 302d each equipped with a probes (with no reference numeral attached) projecting toward the glass substrate. The probe units 302a, 302b, 302c, and 302d are joined to their associated test heads 308a, 308b, 308c, and 308d, respectively. The test heads 308a and 308d are mounted onto one X drive shaft 306a, via their associated Z drive shafts 304a and 304d, respectively. The test heads 308b and 308c are mounted onto the other X drive shaft 306b, via their associated Z drive shafts 304b and 304c, respectively. The X drive shafts 306a and 306b are both mounted onto the Y drive shaft. The probe units, the test heads, and the Z drive shafts, which integrally move as a set of the assembly constituting the movable member, are preferably joined to one another so as to retain rigidity necessary for them to support one another. After the probes are separated from the glass substrate by the Z drive shafts, each movable member is driven along the XY orthogonal coordinate axes by the Y drive shaft and the X drive shafts to be positioned within the XY plane, whereby an operation is performed by bringing the probes to position adjoining or close to the glass substrate by the Z drive shafts. The probes used may be ones comprising springs or may be ones made of flexible material.

The two X drive shafts 306a and 306b may be operated independently from each other such that the resultant of the reaction forces exerted by the X drive shafts 306a and 306b on the Y drive shaft 305 decrease. Further, it is also possible to keep the center of gravity of the drive system as a whole stationary while operating the two X drive shafts 306a and 306b in combination so as to reduce the resultant of the reaction forces exerted by the X drive shafts 306a and 306b on the Y drive shaft 305. For example, provided that the respective sets of the assemblies, including the probe unit, the test head, and the Z drive shaft that move integrally as a movable member, are of substantially the same structure, the X drive shafts 306a and 306b may be operated such that the probe units 302a and 302b are opposed to each other on the X drive shafts and that the probe units 302c and 302d are opposed to each other on the X drive shafts. It should be noted that, as will be appreciated from the details on a movable member drive mechanism to be described later, on those drive shafts, the reaction forces against the driving forces (forces acting during acceleration) cased by movements of the movable members, and the reaction forces against the braking forces (forces acting during deceleration) caused in the case where braking is applied as described later, respectively cancel and reduce each other. Accordingly, the influences due to the movements or the braking of those movable members (the influences due to acceleration, deceleration, and changes in the center of gravity) that are exerted on an external system through the high-rigidity drive shaft become zero, or very little.

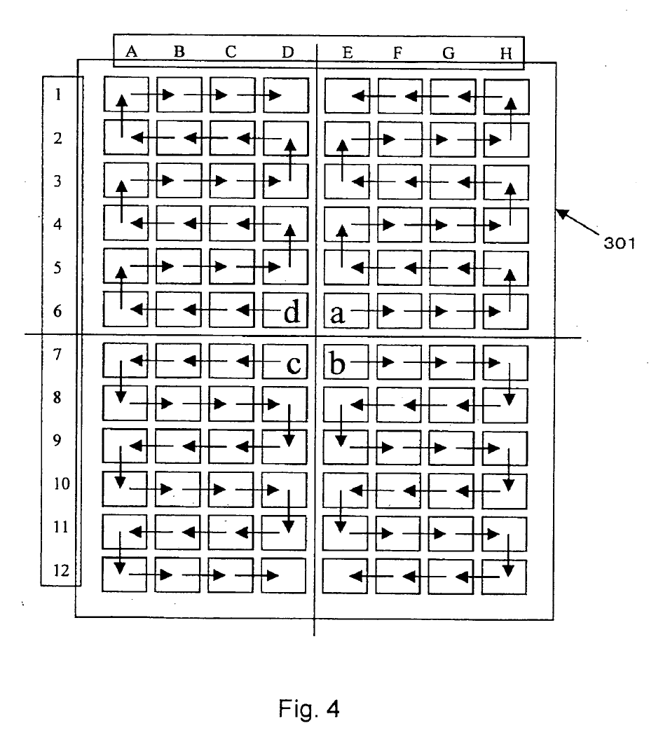

FIG. 4 shows a trajectory chart exemplifying a trajectory along which each of the probe units 302a, 302b, 302c, and 302d travels on a plurality of TFTs for a display panel provided on the glass substrate 301 or on a display panel. The probe units 302a, 302b, 302c, and 302d are driven so as to keep the center of gravity of the device as a whole stationary as much as possible even when the movable members move, with movement of those probe units starting from points a, b, c, and d at the central portion shown in the figure, and travels along the directions as indicated by the arrows in the figure. For example, the probe unit 302a travels along positions indicated by coordinates E6, F6, G6, H6, H5, G5, and soon. Obviously, each movable member may be driven along another trajectory such that the center of gravity of the device as a whole remains stationary as much as possible even when the movable members move. In other words, the trajectory and traveling speed may be determined as appropriate while taking various conditions into account. For example, the inspection speed can be increased with the movable member moving at high speed to reach a location involving high frequency of inspection errors first and the inspection (operation) at that location is performed in precedence to that at other locations.

Next, description will be made on the Y drive shaft 305, the X drive shaft 306a, the X drive shaft 306b, and driving forces thereof, together with a drive mechanism including associated movable members.

In FIGS. 3A through 3C, the Y drive shaft 305, the X drive shaft 306a, and the X drive shaft 306b drive their associated movable members by basically the same drive method to thereby effect positioning. Accordingly, a detailed description on the X drive shaft 306b should be adequate for understanding the operation of the X drive shaft 306a; as for the Y drive shaft 305, a brief mention of the differences should suffice. In the following, the description will be made according to the above basic principles.

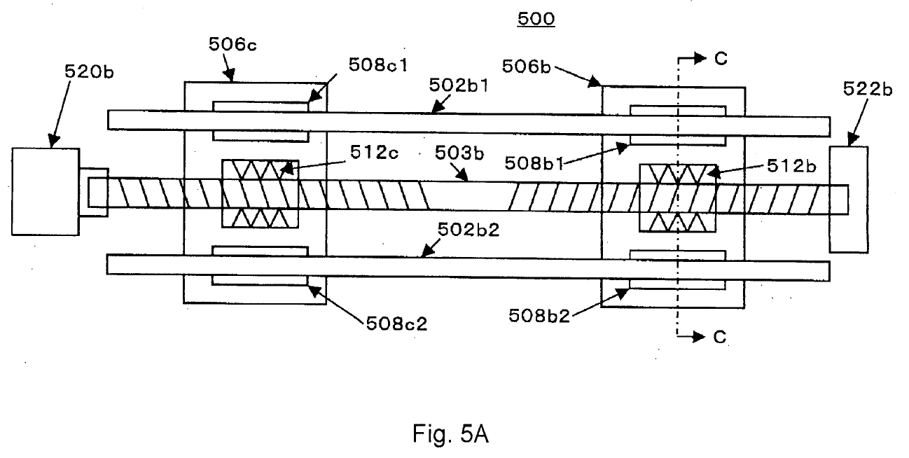

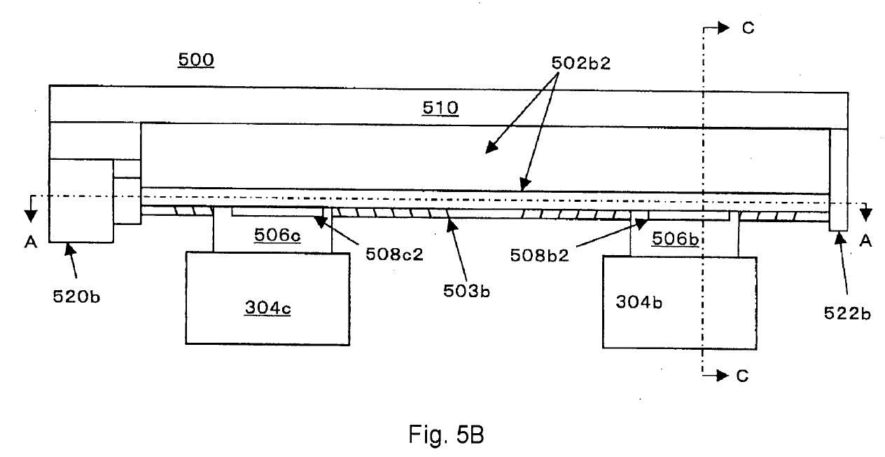

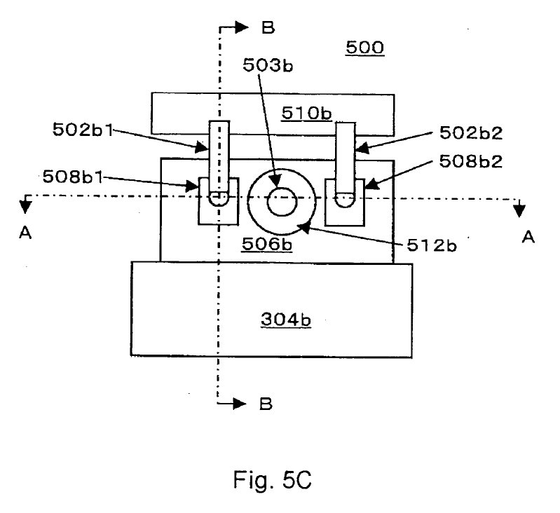

The X drive shaft 306b shown in FIGS. 3A through 3C will be described in detail with reference to FIGS. 5A through 5C as a drive mechanism 500 for the movable member. FIG. 5A is a partial sectional plan view of the drive mechanism 500 taken along the line A-A of FIG. 5C. FIG. 5B is a partial sectional plan view of the drive mechanism 500 taken along the line B-B of FIG. 5C. FIG. 5C is a sectional view of the drive mechanism 500 taken along the line C-C of FIGS. 5A and 5B. Although not shown, applying the figures to FIGS. 3A through 3C, in FIGS. 5B and 5C, the Y drive shaft 305 is located above a base unit 510b that will be described later. Further, in FIGS. 5B and 5C, there are shown the Z drive shafts 304c and 304b located below sliding members 506c and 506b that will be described later, respectively. The remaining portion of the movable member is omitted for the purpose of simplifying the drawings to facilitate the understanding of this invention. The operation relating to the X drive shaft 306a is the same as that relating to the X drive shaft 306b. As for Y drive shaft 305, it is also the same except that the movable member in the following description relates to the X drive shaft.

The base unit 510b of the drive mechanism 500, which is a high-rigidity member driven by the Y drive shaft 305, is a sliding member (corresponding to the sliding members 506c and 506b described later) driven by the Y drive shaft. Alternatively, the base unit 510b may be a member jointed to the sliding member with a high rigidity. When no Y drive shaft is provided to the substrate inspection device, the base unit 510b can be fixed to the frame 310. The base unit 510b has side walls protruding from its opposite ends and includes a servo motor 520b provided to one side wall and a bearing 522b provided to the other side wall, with a helical direction switching ball screw 503b being supported between the both side walls. The helical direction switching ball screw 503b is driven and rotated by the servo motor 520b, and the rotation in forward/reverse direction and the rotation stop are effected by commands from a control portion (not shown). Although not absolutely necessary, the helical direction switching ball screw 503b is preferably kept horizontal during use. In the helical direction switching ball screw 503b, threads are cut in a laterally symmetrical manner from the vicinity of the center thereof (the helical directions of the threads are reversed on the right and left sides at the vicinity of the center thereof), penetrating the sliding members 506c and 506b respectively joined to the Z drive shafts 304c and 304b. The sliding members 506c and 506b are each provided with a screw hole. The respective screw holes are equipped with stationary threads 512c and 512b that come into threaded engagement with the threads on the right and left sides, respectively, of the helical direction switching ball screw 503b that penetrate the screw holes, whereby the sliding members 506c and 506b are suspended by the helical direction switching ball screw 503b. Further, the sliding members 506c and 506b are driven to travel in opposite directions as the helical direction switching ball screw 503b rotates, before being stopped for positioning. Each of the sliding members 506c and 506b further includes a surface opposed to the base unit 510b, and guide grooves are provided on the surface such that they extend along the direction parallel to the direction in which the helical direction switching ball screw 503b extends, and along the both sides of the helical direction switching ball screw 503b. Further, the base unit 510b has guide rails 502b1 and 502b2 extending in the direction parallel to the direction in which the helical direction switching ball screw 503b extends. The guide rails 502b1 and 502b2 have the same height and are located at opposed sides across the helical direction switching ball screw 503b. Through their guide grooves, the sliding members 506c and 506b are guided by the guide rails 502b1 and 502b2. The guide rails 502b1 and 502b2 are fitted into the guide grooves, thereby securing the traveling accuracy of the sliding members 506c and 506b in a stable manner. As shown in the figures, the Z drive shafts 304c and 304b, and the moving members mounted below the Z drive shafts 304c and 304b, are respectively joined to the sliding members 506c and 506b with a high rigidity.

As shown in the figures, the sliding members 506c and 506b may be provided with a brake including brake members 508c1, 508c2, 508b1, and 508b2 provided in their guide grooves. When making a stop, the brakes are actuated to grip each guide rail by the brake members, thus enabling quick stop of the sliding members 506c and 506b themselves. While the brake members 508c1, 508c2, 508b1, and 508b2 are used in the figures, it is also possible to employ a construction in which one brake member is provided to one guide rail, in order to avoid vibration due to the interfering of braking effect by those brake members and to prevent the reaction force generated upon braking from influencing on the frame. For instance, referring to the figures, there may be adopted a construction in which only the brake members 508c1 and 508b2 are used or a construction in which only the brake members 508c2 and 508b1 are used. It should be noted that a reduction in cost can be achieved by providing only two brake members. Even in a construction in which all the (four) brake members are provided, the stability of brake can be enhanced by, for example, actuating only two brake members upon actuation of the brake and by using the other two brake members in case of a failure. Further, referring to FIGS. 5A through 5C, there may be conceived an arrangement of fixing one ends of the respective guide rails to the sliding member 506b and/or sliding member 506c (for example, fixing the guide rails 502b1 and 502b2 to the sliding member 506c or 506b, fixing the guide rail 502b2 to the sliding member 506b while fixing the guide rail 502b1 to the sliding member 506c, or fixing the guide rail 502b2 to the sliding member 506c while fixing the guide rail 502b1 to the sliding member 506b). In this case, the brake members are provided to the (two) end portions to which the guide rails are not fixed, and examples of the possible construction include: a construction in which only the brake members 508c1 and 508b2 are used; a construction in which only the brake members 508c2 and 508b1 are used; a construction in which only the brake members 508c1 and 508c2 are used; and a construction in which only the brake members 508b1 and 508b2 are used.

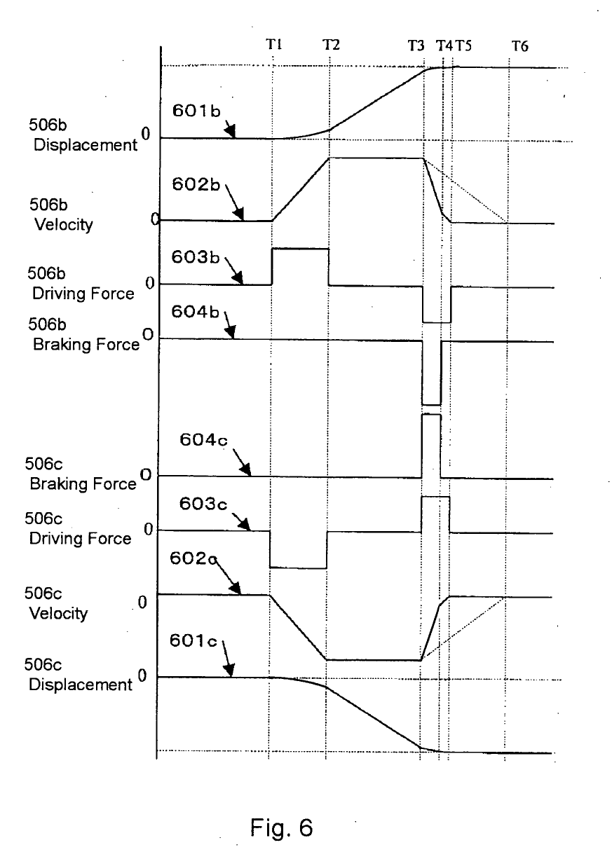

Now, FIG. 6 shows a graph indicating respective operating parameters in time series according to an operation example in the case of the above-described construction. FIG. 6 shows changes with time in displacements 601b and 601c, velocities 602b and 602c, driving forces 603b and 603c for motors, and braking forces 604b and 604c of the brake members, which are operating parameters on the movable members relating to the sliding members 506 band 506c, respectively. Plotted on the graph are respective behaviors of operating parameters in the case where an event occurs at each of times T1 through T6, assuming that the travel direction of the sliding member 506b is chosen as positive and that the two movable members exhibit mechanically equivalent behaviors. It will be appreciated that the operating parameters relating to the sliding member 506b and the corresponding operating parameters relating to the sliding member 506c are equal in magnitude but opposite in sign. Of the time period from T3 to T5 during which the movable members relating to the sliding members 506b and 506c are stopped for positioning, in the earlier stage from T3 to T4, the brake is actuated to generate a braking force, and in the later stage from T4 to T5, the brake is released and fine positional adjustment is performed by the servo motor. In the case where no brake is used, as shown in FIG. 6, the positioning will take a time period up to T6.

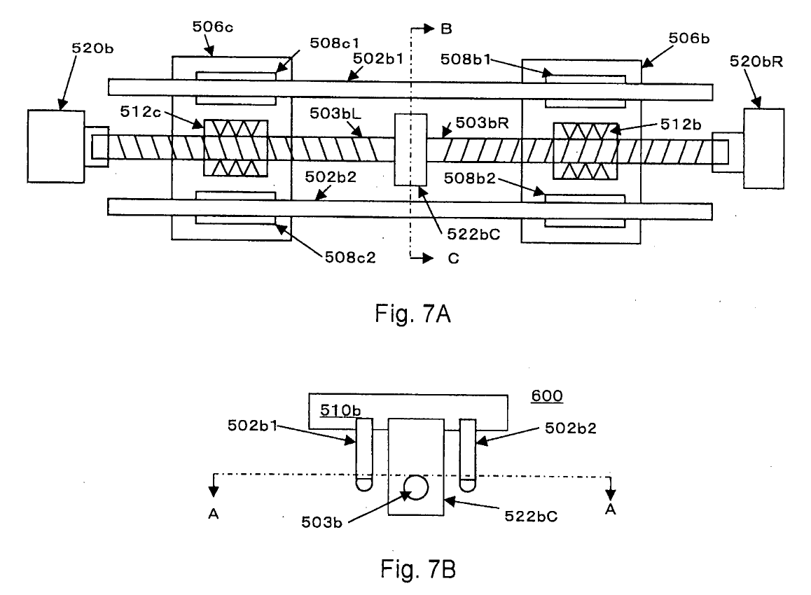

FIGS. 7A and 7B are partial sectional side views of another drive mechanism 600 according to another embodiment of the drive mechanism 500 shown in FIGS. 5A through 5C. FIG. 7A corresponds to FIG. 5A, and FIG. 7B corresponds to FIG. 5C. As shown, FIGS. 7A and 7B illustrate different cross sections. This modified embodiment is as described below. The helical direction switching ball screw 503b is cut in two at the center into a left ball screw 503bL and a right ball screw 503bR, which are both rotatably supported on a bearing 522bC fixed to the base unit 510b. Further, the bearing 522b is replaced by an additional servo motor 520bR. Although this construction reduces the reaction force canceling effect on the ball screws 503bL and 503bR, it gives rise to a new effect of enabling independent control of the movable members relating to the sliding members 506b and 506c. It should be noted, however, that the influence of vibration on the frame increases.

Further modifications of the above and other embodiments are possible. For example, it is possible to replace one of the movable members by a dummy member for reaction force cancellation that does not have a measurement function, in other words, by simply an inexpensive spindle, or to provide each probe unit with a probe position fine adjustment mechanism as an additional positioning device. Other modifications or applications may be employed within the scope of this invention.

For example, for the Y drive shaft 305, it is advantageous to set the distance between the guide rails considerably larger than those of the X drive shafts in order to ensure stable driving and traveling of the X drive shaft. Further, for the Y drive shaft 305, a construction may be adopted in which the frame 310 also serves as the base unit. Furthermore, the number of the guide rails is not limited to two but may be one or three or more. Further, the arrangement positions of the guide rails are not limited to those within the horizontal plane. Further, the component combination may be changed so that the axial centers of the helical direction switching ball screw and guide rails lie within the horizontal plane passing though the center of gravity of the whole assembly consisting of the combination of the sliding member, the X drive shaft, the test head, and the probe unit, thereby realizing more stable driving and traveling.

As described above, according to this invention, it is possible to reduce the vibration generated by the reaction force due to the movement of each movable member and minimize an influence on other components because the vibration transmitted through the probe head shaft is reduced. Thus high-speed, precision positioning can be achieved. Further, the reaction forces caused by the movement of the plural movable members can be kept so as to cancel by each other, whereby the requisite strengths of the base and frame can be made small as compared with the prior art to thereby achieve simplification of the device. Furthermore, the movable members performing operation contribute to the generation of the reaction forces, whereby no additional vibration isolating device is required or a more simple and inexpensive vibration isolating device may suffice.

What is claimed is:

1. A movable operating device comprising:
a frame for fixedly supporting an object having a first surface;
a plurality of movable members movably supported by said frame; and
a movement control device for moving said movable members for positioning,
wherein at least one of said plurality of movable members includes an operating portion that is opposed to the first surface to perform an operation on the first surface, and wherein at least two of said plurality of movable members, that include at least one of said operating portion, are driven by said movement control device so as to cause respective reaction forces that are generated upon driving said at least two movable members and exerted on said frame to be reduced by each other.

2. The movable operating device as defined in claim 1, wherein said at least two of said plurality of movable members are movable in opposite directions along trajectories that are in line symmetry or in point symmetry to each other.

3. The movable operating device as defined in claim 1, further comprising a ball screw device driven by said movement control device, wherein said at least two of said plurality of movable members are supported by said frame with said ball screw device interposed therebetween.

4. The movable operating device as defined in claim 3, wherein said ball screw device comprises a first portion and a second portion, said first portion and said second portion respectively supporting at least one of said plurality of movable members, and
wherein said first portion and said second portion of said ball screw device are each driven by said movement control device for positioning respective of said movable members supported by said first portion and said second portion of said ball screw device.

5. The movable operating device as defined in claim 1, wherein said movable control device further comprises a brake device provided to at least one of said plurality of movable members, for braking said at least one movable member.

6. The movable operating device as defined in claim 5, wherein said brake device is provided to only one of said at least two of said plurality of movable members.

7. The movable operating device as defined in claim 1, wherein said at least one of said plurality of movable members which comprises the operating portion further comprises an alignment device for moving said operating portion provided to said at least one of said movable members.

8. The movable operating device as defined in claim 1, wherein at least one of said plurality of movable members is replaced by a dummy member.

9. The movable operating device as defined in claim 1, wherein said plurality of movable members comprise at least a first set of movable members and a second set of movable members, and wherein the movable members belonging to said second set are indirectly supported by said frame by being movably mounted to said movable members belonging to said first set.

10. The movable operating device as defined in claim 1, wherein:
said at least one of said plurality of movable members comprises a test head;
said operating portion comprises a probe; and
said movable operating device is operable to perform an inspection on a substrate that is the object.

11. A method of controlling a movable operating device, said movable operating device including: a frame; a plurality of movable members movably supported by said frame; and a movement control device for moving said movable members for positioning, said method comprising:
fixedly supporting an object having a first surface on said frame;
moving at least two of said plurality of movable members in an opposed manner with respect to the first surface; and
positioning and stopping said at least two of said plurality of movable members in place,
wherein said at least two of said plurality of movable members are driven by said movement control device so as to cause respective reaction forces that are generated upon driving said at least two movable members and exerted on the frame to be reduced by each other.

12. The method of controlling a movable operating device as defined in claim 11, wherein at least one in said at least two of said plurality of movable members comprises an operating portion opposed in an adjoining manner or in proximity to the first surface, and
wherein the method further comprises performing an operation on the first surface by said operating portion.

13. The method of controlling a movable operating device as defined in claim 11, wherein said at least two of said plurality of movable members are moved in opposite directions along trajectories that are in line symmetry or in point symmetry to each other.

14. The method of controlling a movable operating device as defined in claim 11, wherein said at least two of said plurality of movable members are supported by said frame with a ball screw device driven by said movement control device.

15. The method of controlling a movable operating device as defined in claim 14, wherein said ball screw device has a first portion and a second portion, said first portion and said second portion of said ball screw device each supporting at least one of said plurality of movable members, and
wherein said first portion and said second portion of said ball screw device are each driven by the movement control device for positioning respective of said movable members supported by said first portion and said second portion of said ball screw device.

16. The method of controlling a movable operating device as defined in claim 11, wherein said positioning and stopping of said at least two of said plurality of movable members comprises actuating a brake device for braking at least one of said plurality of movable members.

17. The method of controlling a movable operating device as defined in claim 16, wherein said actuating of said brake device comprises actuating said brake device on only one of said at least two of the plurality of movable members.

18. The method of controlling a movable operating device as defined in claim 17, wherein said positioning and stopping of said at least two of said plurality of movable members further comprises performing positioning after actuating said brake device.

19. The method of controlling a movable operating device as defined in claim 18, wherein said movement control device comprises a motor that drives said ball screw device, and wherein the positioning in said positioning and stopping of said at least two of said plurality of movable members is performed through said motor.

20. The method of controlling a movable operating device as defined in claim 11, wherein at least one of said plurality of movable members is replaced by a dummy member.
